(19) United States
(12) Patent Application Publication
(10) Pub. No.: US 2009/0091026 A1
(43) Pub. Date: Apr. 9, 2009

(54) Stackable semiconductor package having plural pillars per pad

(75) Inventor: Wen-Jeng Fan, Hukou Shiang (TW)

Correspondence Address: Joe McKinney Muncy, PO Box 1364, Fairfax, VA, 22038-1364, US

(73) Assignee: POWERTECH TECHNOLOGY INC.

(21) Appl. No.: 11/905,946

(22) Filed: Oct. 5, 2007

(51) Int. Cl. H01L 23/49

(52) U.S. Cl. 257/737; 257/E23.024

(57) ABSTRACT

A stackable semiconductor package is revealed, primarily comprising a chip carrier, a chip, and a plurality of bottom bump sets. The chip carrier has a plurality of stacking pads disposed on the top surface and a plurality of bump pads on the bottom surface. The chip is disposed on and electrically connected to the chip carrier. The bottom bump sets are disposed on the corresponding bump pads and each consists of a plurality of conductive pillars. Solder-filling gaps are formed between the adjacent conductive pillars for filling and holding solder paste so that the soldering area can be increase and the anchoring effect can be enhanced due to complicated the soldering interfaces to achieve higher soldering reliability and less cracks at the soldering interfaces.

### FIELD OF THE INVENTION

The present invention relates to a 3D (three-dimensional) stackable semiconductor package, especially to a 3D stackable semiconductor package with plural pillars per pad which can be implemented in Package-On-Package devices (POP).

### BACKGROUND OF THE INVENTION

When the dimension of a printed circuit board becomes smaller and smaller, the available surface for placing IC components becomes smaller and smaller as well. Three-dimensional (3D) stacking technologies of semiconductor packages are developed to vertically stack a plurality of stackable semiconductor packages to be Package-On-Package device (POP) to meet the requirements of high density components with minimum footprints. However, soldering defects are the major issues during POP stacking processes. Moreover, the soldering interfaces between fine-pitch terminals are vulnerable to thermal stresses leading to broken interfaces and causing electrical open.

In U.S. Pat. No. 6,476,503 by Fujitsu and in US patent publication No. 2006/0138647 by Tessera, two micro contact structures with pillar bumps or needle bumps to solder with solder paste for 3D package stacking have been revealed.

As shown in FIG. 1, a conventional stackable semiconductor package 100 primarily comprises a chip carrier 110, a chip 120 and a plurality of pillar bumps 130. The chip carrier 110 has a top surface 111 and a bottom surface 112 where a plurality of stacking pads 113 are disposed on the top surface 111 and a plurality of bump pads 114 on the bottom surface 112. The chip 120 is disposed on and electrically connected to the chip carrier 110 by a plurality of bonding wires 121 passing through a wire-bonding slot 115 through the chip carrier 110 where the bonding wires 121 are encapsulated by an encapsulant 140. The pillar bumps 130 are one-on-one disposed on the corresponding bump pads 114. Moreover, only one pillar bump 130 is disposed on one corresponding bump pad 114 of one stackable semiconductor package 100 and is soldering to the stacking pads 113 of another package 100 by solder paste 150 to achieve micro contacts for higher pin counts, larger routing areas, and smaller POP stacking standoffs.

However, the pillar bumps 130 are sensitive to thermal or mechanical stresses. When the pillar bumps 130 experience thermal or mechanical stresses, cracks will form at the soldering interfaces of the pillar bumps 130 and will crack along the surfaces of the pillar bumps 130 until the bump pads 114 leading to electrical open. Furthermore, during reflowing processes for POP stacking, solder paste 150 become fluid. Once the chip carrier 110 is warpaged or the bonding force is uneven, the fluid solder paste 150 will flood on the chip carrier 110 leading to bridging shorts between the micro contacts of the pillar bumps 130.

### SUMMARY OF THE INVENTION

The main purpose of the present invention is to provide a stackable semiconductor package with plural pillars per pad where a bump set consisting of a plurality of conductive pillars is disposed on each bump pad to increase soldering joint area to achieve higher soldering reliability and to make the soldering interfaces more robust through a complicated bump set to reduce the formation and the impact of cracks.

The second purpose of the present invention is to provide a stackable semiconductor package with plural pillars per pad where a bump set disposed on each bump pad offers solder-filling gaps so that the solder paste will fill and hold inside the bump set during reflowing. Even with substrate warpage or tilt, the solder paste will not experience stresses leading to flooding of solder paste and causing bridging shorts.

According to the present invention, a stackable semiconductor package primarily comprises a chip carrier, a chip, and a plurality of bottom bump set. The chip carrier has a top surface and a bottom surface, what formed on the top surface are a plurality of stacking pads and on the bottom surface are a plurality of bump pads. The chip is disposed and electrically connected to the chip carrier. Each bottom bump set consists of a plurality of conductive pillars and is disposed on the corresponding one of the bump pads by set-on-pad configuration. Moreover, there are solder-filling gaps formed between the adjacent pillars on each bump pad for filling and holding the solder paste.

### DESCRIPTION OF THE DRAWINGS

FIG. 1 shows a cross-sectional view of a plurality of conventional stackable semiconductor packages.

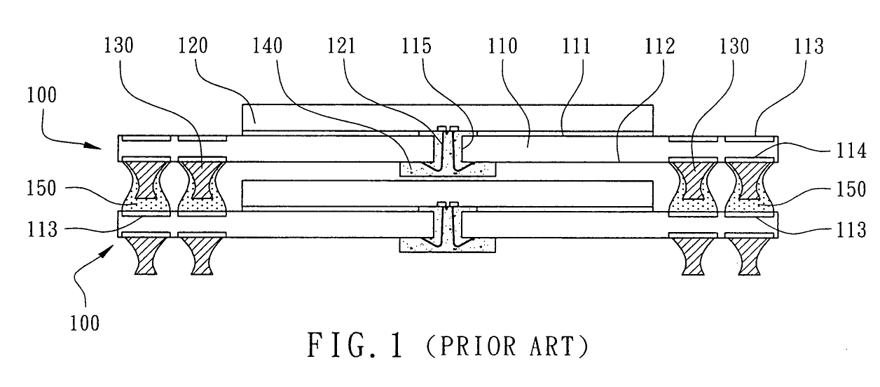

FIG. 2 shows a cross-sectional view of a plurality of stackable semiconductor packages according to the first embodiment of the present invention.

FIG. 3 shows a 3D view of one bottom bump set on pad of a stackable semiconductor package according to the first embodiment of the present invention.

FIGS. 4A and 4B show the top view and the corresponding bottom view of a plurality of conductive pillars of one bottom bump set on pad from the stackable semiconductor package according to the first embodiment of the present invention.

FIG. 5 shows a cross-sectional view of another stackable semiconductor package according to the second embodiment of the present invention.

FIG. 6 shows the interlaced view of the top bump set to the corresponding bottom bump set of the stackable semiconductor package according to the second embodiment of the present invention.

FIG. 7 shows a cross-sectional view of a plurality of stackable semiconductor packages mounted on a printed circuit board according to the third embodiment of the present invention.

### DETAIL DESCRIPTION OF THE INVENTION

Please refer to the attached drawings, the present invention will be described by means of embodiments below.

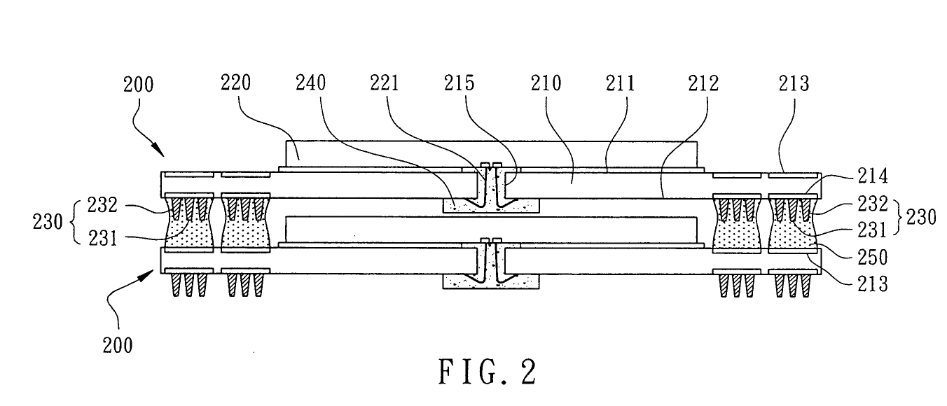

According to the first embodiment of the present invention, a POP device includes two stackable semiconductor packages 200 is shown in FIG. 2, however, more stackable semiconductor packages 200 can be stacked such as three or four or more but not limited by stacking only two. Each stackable semiconductor package 200 primarily comprises a chip carrier 210, a chip 220, and a plurality of bottom bump sets 230. The chip carrier 210 is a single layer, double layer, or multi-layer printed circuit board. The chip carrier 210 has a top surface 211 and a bottom surface 212 where a plurality of stacking pads 213 are disposed on the top surface 211 as the first pads of the chip carrier 210 and a plurality of bump pads 214 are disposed on the bottom surface 212 as the second pads of the chip carrier 210.

The chip 220 is attached and electrically connected to the chip carrier 210, for example, the active surface of the chip 220 is attached to the top surface 211 of the chip carrier 210 by a die-attaching material, then the bonding pads of the chip 220 are electrically connected to the inner fingers (not shown in the figure) of the chip carrier 210 by a plurality of bonding wires 221 formed by wire bonding. In the present embodiment, the chip carrier 210 has a wire-bonding slot 215 through the top surface 211 and the bottom surface 212. The bonding wires 221 can pass through the wire-bonding slot 215 to electrically connect the chip 220 to the chip carrier 210 with the back surface of the chip 220 exposed from the top surface 211 of the chip carrier 210. In a different embodiment, the chip 220 can electrically connect to the chip carrier 210 by flip-chip mounting.

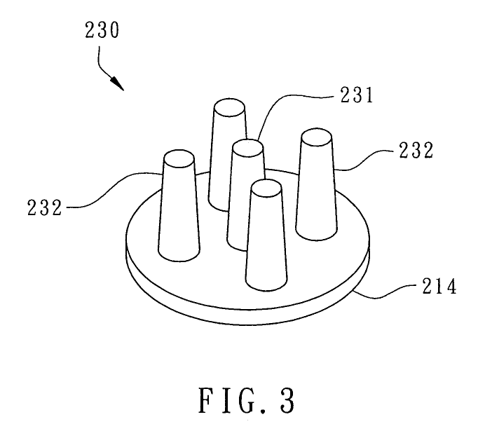

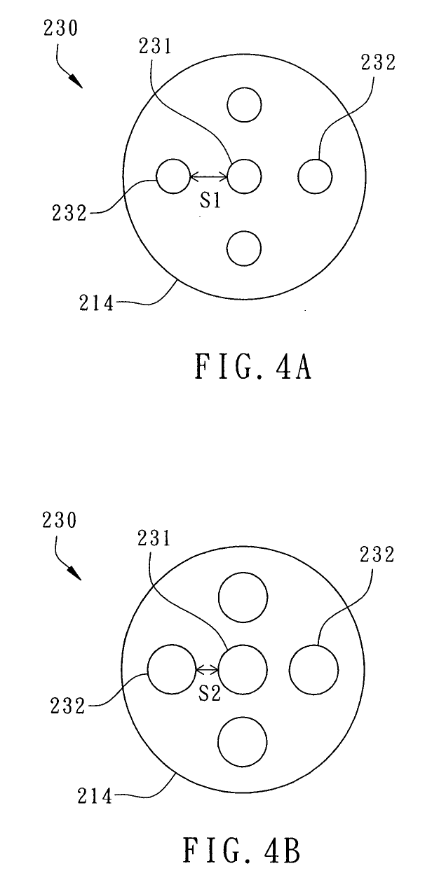

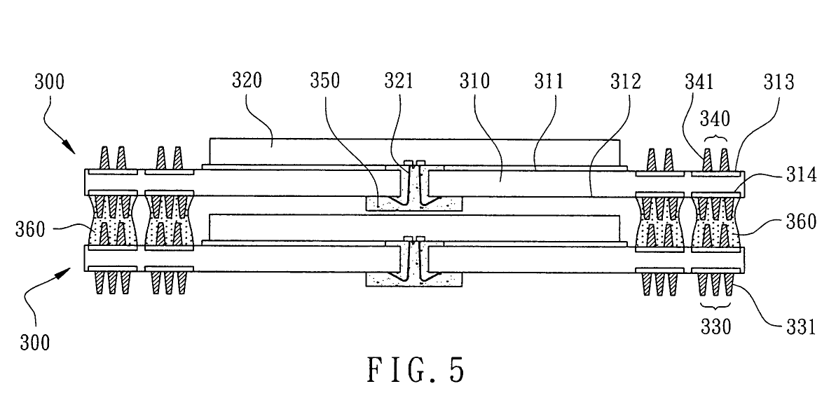

In the present embodiment, the stackable semiconductor package 200 further comprises an encapsulant 240 formed by molding or dispensing in the wire-bonding slot 215 and extruded from the bottom surface 212 to encapsulate the bonding wires 221. The bottom bump sets 230 are disposed on the bump pads 214 with one set aligned with one pad. Each bottom bump set 230 on each bump pad 214 consists of a plurality of conductive pillars 231 and 232. As shown in FIG. 3, in the present embodiment, each bottom bump set 230 on each bump pad 214 includes a central pillar 231 and a plurality of peripheral pillars 232. With the disposition of central pillar 231, the solder-filling gaps and the pitches between the peripheral pillars 232 and between from the central pillar 231 to the peripheral pillars 232 can be maintained and kept. The conductive pillars 231 and 232 may be copper posts formed by plating, gold post formed by wire bonding, copper pillars formed by etching thick copper films, or other metal pillars. Preferably, the conductive pillars 231 and 232 in the same bottom bump set 230 are arranged in an array. As shown in FIGS. 4A and 4B, there are solder-filling gaps S1 and S2 between the adjacent conductive pillars 231 and 232 for filling and holding solder paste where the solder-filling gap S1 is the distance between the tips of the adjacent conductive pillars 231 and 232 and the solder-filling gap S2 is the one between the bases of the adjacent conductive pillars 231 and 232. Preferably, the solder-filling gap S1 is greater than the solder-filling gap S2. During reflowing, the fluid solder paste 250 (as shown in FIG. 2) will be filled into and held in the solder-filling gaps S1 and S2 between the conductive pillars 231 and 232 without flooding. When one stackable semiconductor package 200 is stacked above another stackable semiconductor package 200, the bottom bump sets 230 on the bump pads 214 are soldered and joined to the stacking pads 213 of another stackable semiconductor package 200 by solder paste 250 to become a POP device. To be more specific, the conductive pillars 231 and 232 have trapezoid cross-sections with narrow tips and wide bases such as hemi-spherical cones or hemi-square cones. According to the choice of positive or negative photo resist and etching solutions with the technique of over-exposure, under-exposure or under-etching to fabricate the conductive pillars 231 and 232. Normally the solder paste 250 is lead-free solder paste such as 96.5% of tin-3% of silver-0.5% of copper where the wettability is good for soldering when the reflow temperature is above 217° C., or even as high as 245° C. or even reach to 260° C. The conductive pillars 231 and 232 may be copper pillars, gold pillars, or metal pillars with melting points higher than the reflow temperature mentioned above. Therefore, the bottom bump sets 230 have increased the soldering area and enhanced the anchoring effects to achieve better soldering reliability and reduce the formation and the impact of cracks at the soldering interface. Even with a broken interface between one of the peripheral pillars 232 and the solder paste 250, there are still good soldering joints between the central pillar 231 and the solder paste 250 and between the rest of the peripheral pillars 232 and the solder paste 250 so that there is no electrical open issue, moreover, the reliability of POP device is enhanced. According to the second embodiment of the present invention, another stackable semiconductor package is revealed as shown in FIG. 5. The stackable semiconductor package 300 primarily comprises a chip carrier 310, a chip 320, and a plurality of bottom bump sets 330 which is about the same as the first embodiment. However, the stackable semiconductor package 300 further comprises a plurality of top bump sets 340 on the chip carrier 310.

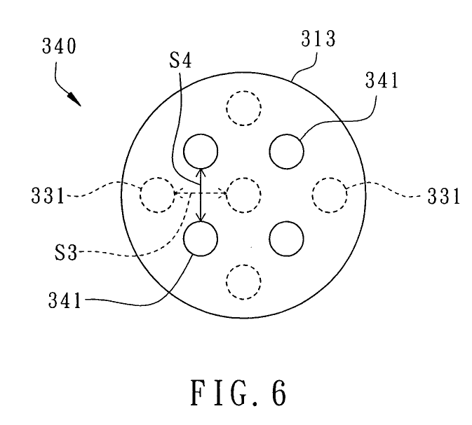

The chip carrier 310 has a top surface 311 and a bottom surface 312 where a plurality of stacking pads 313 are disposed on the top surface 311 and a plurality of bump pads 314 on the bottom surface 312. The chip 320 is disposed and electrically connected to the chip carrier 310. The bottom bump sets 330 are disposed on the corresponding bump pads 314 by one set aligned with one pad. Each bottom bump set 330 consists of a plurality of conductive pillars 331. As shown in FIG. 6, there are solder-filling gaps S3 formed between the adjacent conductive pillars 331 of each bottom bump set 330 on each bump pad 314 for filling and holding the solder paste 360 (as shown in FIG. 5).

As shown in FIG. 5 and FIG. 6, the top bump sets 340 are disposed on the corresponding stacking pads 313, each top bump set 340 consists of a plurality of conductive pillars 341. As shown in FIG. 6 again, there are solder-filling gaps S4 formed between the adjacent conductive pillars 341 of each top bump set 340 on each stacking pads 313 for filling and holding the solder paste 360. Preferably, the conductive pillars 341 of the top bump set 340 and the conductive pillars 331 of the corresponding bottom bump set 330 are arranged in stagger to achieve better anchoring and locking effects (as shown in FIGS. 5 and 6). As shown in FIG. 6 again, the solder-filling gaps S4 between the adjacent conductive pillars 341 of the top bump set 340 and the solder-filling gaps S3 between the adjacent conductive pillars 331 of the bottom bump set 330 are equal spacing and are disposed in vertical direction. Therefore, during stacking a plurality of stackable semiconductor package 300, the solder paste 360 will join the bottom bump sets 330 beneath an upper package 300 to the corresponding top bump sets 340 on a lower package 300 with larger soldering areas and complicated anchoring structures to enhance the soldering reliability of POP device and to prevent flooding of solder paste 360.

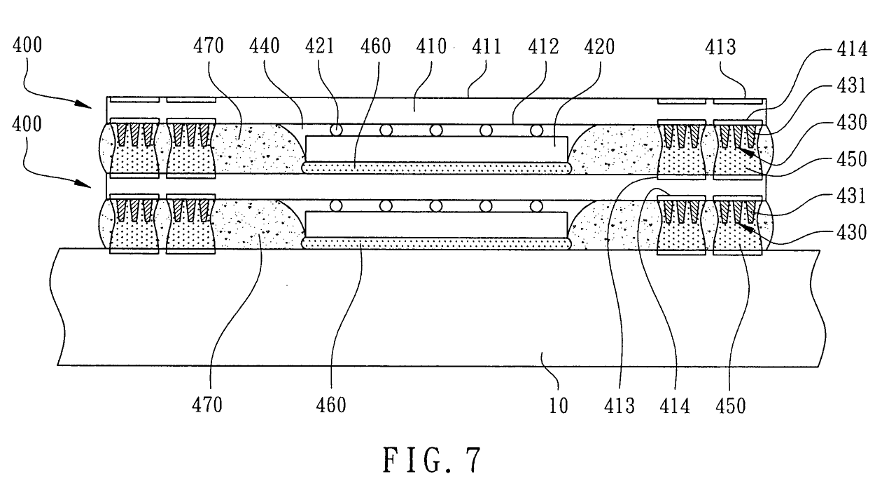

According to the third embodiment of the present invention as shown in FIG. 7, a plurality of stackable semiconductor packages 400 are stacked and mounted on a printed circuit board 10. The stackable semiconductor package 400 primarily comprises a chip carrier 410, a chip 420, and a plurality of bottom bump sets 430. The chip carrier 410 has a top surface 411 and a bottom surface 412 where a plurality of first pads 413 such as stacking pads are disposed on the top surface 411. A plurality of second pads 414 such as bump pads are disposed on the bottom surface 412. In the present embodiment, the chip 420 has a plurality of bumps 421 to electrically connect the chip 420 to the chip carrier 410 by flip chip technologies. If desired, the bumps 421 are encapsulated by an encapsulant 440 such as underfill materials.

In the present embodiment, the chip 420 is disposed on the bottom surface 412 of the chip carrier 410. The bottom bump sets 430 are disposed on the second pads 414 and arranged around the peripheries of the chip 420 so that the top surface 411 of the chip carrier 410 is flat not to damage the chip 420 nor the bottom bump sets 430. Preferably, the back surface of the chip 420 is exposed from the bottom surface 412 of the chip carrier 410 for heat dissipation.

Each bottom bump set 430 on the corresponding second pad 414 consists of a plurality of conductive pillars 431 where there are solder-filling gaps formed between the adjacent conductive pillars 431 on each second pad 414 for filling and holding the solder paste 450.

As shown in FIG. 7, when a plurality of stackable semiconductor packages 400 are stacked and mounted on a printed circuit board 10. Preferably, each stackable semiconductor package 400 further comprises a thermal-coupling component 460, such as thermal interface materials (TIM), or heat grease, formed on the exposed back surface of the chip 420 to thermally couple to the printed circuit board 10 or to the chip carrier 410 of another stackable semiconductor package 400 below for good heat dissipation. Each stackable semiconductor package 400 further comprises an encapsulant 470 such as underfill materials formed on the bottom surface 412 of the chip carrier 410 to encapsulate the solder paste 450 and the chip 420 to eliminate any possible contamination or electrical shorts causing by dusts falling or accumulating in the package-stacking spacing.

The above description of embodiments of this invention is intended to be illustrative and not limiting. Other embodiments of this invention will be obvious to those skilled in the art in view of the above disclosure.

What is claimed is:

1. A stackable semiconductor package comprising:
a chip carrier having a top surface, a bottom surface, a plurality of first pads disposed on the top surface and a plurality of second pads on the bottom surface;
a chip disposed and electrically connected to the chip carrier;
a plurality of bottom bump sets disposed on the corresponding second pads, each bottom bump set consisting of a plurality of conductive pillars, wherein there are solder-filling gaps formed between the adjacent conductive pillars on each second pad, said bottom bump sets partially occupy the second pads on the bottom surface of the chip carrier; and
a plurality of top bump sets consisting of a plurality of conductive pillars, which partially occupy the first pads on the top surface of the chip carrier, the first pads being vertically aligned with the second pads, the first pads having a first exposed pattern from the top bump sets for receiving solder paste.

2. The stackable semiconductor package as claimed in claim 1, wherein the solder-filling gaps are wider at the tops of the adjacent pillars and are narrower at the bases of the adjacent pillars.

3. The stackable semiconductor package as claimed in claim 1, wherein the conductive pillars on each second pad are arranged in an array.

4. The stackable semiconductor package as claimed in claim 1, wherein each bottom bump set comprises a central pillar and a plurality of peripheral pillars.

5. (canceled)

6. The stackable semiconductor package as claimed in claim 1, wherein the conductive pillars on each first pad and on the corresponding second pad are offset said pillars of each first pad being not vertically aligned with the pillars of the corresponding second pad, so that the second pads have a second exposed pattern from the bottom bump sets different from the first exposed pattern.

7. The stackable semiconductor package as claimed in claim 1, wherein the solder-filling gaps between the adjacent conductive pillars of the top bump sets and the solder-filling gaps between the adjacent conductive pillars of the bottom bump sets are equal spacing in the vertical direction.

8. The stackable semiconductor package as claimed in claim 1, wherein the chip carrier is a printed circuit board.

9. The stackable semiconductor package as claimed in claim 8, wherein the chip carrier has a wire-bonding slot for passing through a plurality of bonding wires to electrically connect the chip to the chip carrier.

10. The stackable semiconductor package as claimed in claim 9, further comprising an encapsulant formed in the wire-bonding slot and extruded from the bottom surface to encapsulate the bonding wires.

11. The stackable semiconductor package as claimed in claim 1, wherein the chip is disposed on the bottom surface of the chip carrier and the bottom bump sets are arranged around the chip.

12. The stackable semiconductor package as claimed in claim 11, wherein a back surface of the chip is exposed from the bottom surface of the chip carrier.

13. The stackable semiconductor package as claimed in claim 12, further comprising a thermal-coupling component formed on the exposed back surface of the chip.

14. The stackable semiconductor package as claimed in claim 11, further comprising an encapsulant formed on the bottom surface of the chip carrier.

15. The stackable semiconductor package as claimed in claim 1, wherein the conductive pillars have trapezoid cross-sections with narrow tips and wide bases.

16. The stackable semiconductor package as claimed in claim 1, further comprising solder paste filling up the solder-filling gap between the conductive pillars.

17. The stackable semiconductor package as claimed in claim 1, wherein the conductive pillars on each second pad include a central pillar and a plurality of peripheral pillars.
